(19) United States
(12) Patent Application Publication
(10) Pub. No.: US 2016/0020103 A1
(43) Pub. Date: Jan. 21, 2016

(54) BARRIER LAYER, METHOD FOR FABRICATING THE SAME, THIN FILM TRANSISTOR AND ARRAY SUBSTRATE

(71) Applicant: BOE TECHNOLOGY GROUP CO., LTD., Beijing (CN)

(72) Inventor: Xiang LIU, Beijing (CN)

(73) Assignee: BOE TECHNOLOGY GROUP CO., LTD., Beijing (CN)

(21) Appl. No.: 14/362,423

(22) PCT Filed: Dec. 5, 2013
(86) PCT No.: PCT/CN2013/088568

§ 371 Date: Jun. 3, 2014

(30) Foreign Application Priority Data
Sep. 4, 2013 (CN) 201310397184.5

(51) Int. Cl. H01L 21/283; H01L 27/12; H01L 29/45

(52) U.S. Cl. CPC H01L 21/283; H01L 29/45; H01L 27/1214

(57) ABSTRACT

A barrier layer, a method for fabricating the same, a thin film transistor (TFT) and an array substrate are disclosed and related to display technology field. When the barrier layer (40) is applied to a TFT, it can block Cu atoms from diffusing to other layers, thereby reducing the harm to the performance of the TFT. The barrier layer (40) comprises at least two layers (401, 402) of conductive films; grain boundaries (70) in any layer (401, 402) of the conductive films are arranged in a staggered manner relative to grain boundaries (70) in another layer (401, 402) of the conductive films contacting therewith.

### TECHNICAL FIELD

Embodiments of the invention relate to a barrier layer, a method for fabricating the same, a thin film transistor (TFT) and an array substrate.

### BACKGROUND

Recently, large size, high resolution liquid crystal televisions have gradually become a mainstream trend for the development of TFT Liquid Crystal Displays (TFT-LCDs), and this trend requires driver circuits with higher frequencies to improve the display quality but makes the phenomenon of image signal delay in the TFT-LCDs even severer. Delay of the TFT-LED signal is mainly determined by T=RC, where T is signal transmission speed, R is signal resistance, and C is related capacitance.

Currently, metals with relatively stable chemical properties but relatively high resistivity such as tantalum (Ta), chrome (Cr), molybdenum (Mo) or alloys thereof are used as the materials for metal electrodes. With the increase in the size of TFT-LCDs, the length of gate scan lines is also increased, causing signal time delay to increase accordingly. When the signal delay is increased to a certain extent, some pixels may be not charged sufficiently, thereby causing uneven brightness and decrease if the contrast ratio of the TFT-LCDs, which severely influences the display quality of images.

In view of the above, metal copper with low resistance is currently used as the source/drain electrode of the TFT so as to solve the problem. However, copper atoms can easily diffuse to the semiconductor active layer, the gate insulation layer and the passivation layer under the action of high temperatures or an external electric field (E-field), degrading or even disabling the performance of the device. Therefore, generally it is necessary to deposit a barrier layer before depositing the copper metal film.

A barrier layer should have good thermal stability, good conductivity and the like. Therefore, a material for the barrier layer is generally a metal element material or an alloy thereof with high melting point, excellent conductivity, such as molybdenum (Mo), titanium (Ti), Mo—Ti alloy, Ti alloy or the like.

In term of its structure, an optimal barrier layer is made of a monocrystalline material. However, monocrystalline materials are not easy to grow and of high cost, making mass production infeasible. A film formed of a metal or an alloy is generally a polycrystalline film, in which a number of grain boundary defects exist, which often forms channels for copper atoms to diffuse therethrough. However, even a trace mount of copper atoms can compromise the performance of the TFT device.

In the following, an example of metal element Mo being used for a barrier layer will be described. As illustrated in FIG. 1, in a barrier layer 40, grains grow vertically to form grain boundaries 70, forming diffusion channels between a source/drain metal layer 50 made of copper and a semiconductor active layer 30. When copper atoms 60 are acted by heat or application of an external E-field, a part of the copper atoms 60 can move cross the grain boundaries and diffuse to the semiconductor active layer 30, which will affect the performance of a TFT.

### SUMMARY

Embodiments of the invention provide a barrier layer, a method for fabricating the same, a TFT and an array substrate that can prevent the diffusion of copper atoms.

A first aspect of the invention provides a barrier layer; the barrier layer comprises at least two layers of conductive films, and grain boundaries in any layer of the conductive films are arranged in a staggered manner relative to grain boundaries in another layer of the conductive films contacting therewith.

As an example, the at least two layers of conductive films comprise at least a first layer of conductive film and a second layer of conductive film, and both the first layer of conductive film and the second layer of conductive film comprise metal elements having high thermal stability and low resistivity.

As an example, the at least two layers of conductive films comprise at least a first layer of conductive film and a second layer of conductive film; the first layer of conductive film comprises a metal element having high thermal stability and low resistivity; and the second layer of conductive film comprises a compound or an alloy formed from the metal element having high thermal stability and low resistivity. As an example, the compound comprises oxide, nitride, or oxynitride formed from the metal element having high thermal stability and low resistivity. As an example, the metal element having high thermal stability and low resistivity comprises molybdenum, titanium, tungsten, tantalum, zirconium, cobalt or hafnium.

As an example, a thickness of any layer of the conductive films is 30˜500 Å.

Another aspect of the invention further provides a barrier layer; the barrier layer comprises at least one barrier unit, any barrier unit comprises a layer of upper conductive film and a layer of lower conductive film, and the upper conductive film comprises a grain-boundary-free conductive film.

As an example, the lower conductive film comprises a metal element having high thermal stability and low resistivity or an alloy formed from the metal element having high thermal stability and low resistivity. As an example, the metal element having high thermal stability and low resistivity comprises molybdenum, titanium, tungsten, tantalum, zirconium, cobalt or hafnium.

As an example, a thickness of any layer of the conductive films is 30˜300 Å.

Still another aspect of the invention further provides a barrier layer; the barrier layer comprises a third conductive film having grain boundaries and further comprises grain boundary blockages at the grain boundaries of the third conductive film, for filling the grain boundaries of the third conductive film.

As an example, the third conductive film comprises a metal element having high thermal stability and low resistivity or an alloy formed from the metal element having high thermal stability and low resistivity; the grain boundary blockages comprise oxide, nitride, or oxynitride formed from the metal element having high thermal stability and low resistivity. As an example, the metal element having high thermal stability and low resistivity comprises molybdenum, titanium, tungsten, tantalum, zirconium, cobalt or hafnium.

As an example, a thickness of the third conductive film is 30˜1500 Å.

Yet another aspect of the invention further provides a TFT, comprising a gate electrode, a gate insulation layer, a semiconductor active layer, a source/drain metal layer, and any of the above barrier layers.

Another aspect of the invention further provides an array substrate, comprising a substrate and the above disposed on the substrate.

Another aspect of the invention further provides a method for fabricating a barrier layer; the method comprises: forming at least two layers of conductive films on a base substrate; grain boundaries in any layer of the conductive films is arranged in a staggered manner relative to grain boundaries in another layer of the conductive films contacting therewith.

As an example, at least a first layer of conductive film and a second layer of conductive film layer both comprising metal elements having high thermal stability and low resistivity are formed on the base substrate.

As an example, at least a first layer of conductive film comprising a metal element having high thermal stability and low resistivity and a second layer of conductive film comprising a compound or an alloy formed from the metal element having high thermal stability and low resistivity are formed on the base substrate. As an example, the metal element having high thermal stability and low resistivity comprises molybdenum, titanium, tungsten, tantalum, zirconium, cobalt or hafnium.

As an example, a thickness of any layer of the conductive films is 30˜500 Å.

Still another aspect of the invention further provides a method for fabricating a barrier layer; the method comprises forming at least a barrier unit on a base substrate, any barrier unit comprises a layer of upper conductive film and a layer of lower conductive film, and the upper conductive film comprises a grain-boundary-free conductive film.

As an example, a layer of lower conductive film is formed on the base substrate, and the lower conductive film comprises a metal element having high thermal stability and low resistivity or an alloy formed from the metal element having high thermal stability and low resistivity. As an example, oxygen, or nitrogen or a mixture of oxygen and nitrogen is introduced to a surface of the lower conductive film that faces the base substrate to form the upper conductive film, and the upper conductive film is a grain-boundary-free conductive film. As an example, the metal element having high thermal stability and low resistivity comprises molybdenum, titanium, tungsten, tantalum, zirconium, cobalt or hafnium.

As an example, wherein a thickness of any barrier unit is 30˜300 Å.

Yet another aspect of the invention further provides a method for fabricating a barrier layer; the method comprises: forming a third conductive film having grain boundaries on a base substrate and forming grain boundary blockages at the grain boundaries of the third conductive film, the grain boundary blockages are configured for filling the grain boundaries of the third conductive film.

As an example, a third conductive film having grain boundaries is formed on the base substrate, and the third conductive film comprises a metal element having high thermal stability and low resistivity or an alloy formed from the metal element having high thermal stability and low resistivity. As an example, oxygen, or nitrogen or a mixture of oxygen and nitrogen is introduced to a surface of the third conductive film that faces the base substrate, to form the grain boundary blockages at the grain boundaries of the third conductive film, and the grain boundary blockages are configured for filling the grain boundaries of the third conductive film; the grain boundary blockages comprise oxide, nitride, or oxynitride formed from the metal element having high thermal stability and low resistivity. As an example, the metal element having high thermal stability and low resistivity comprises molybdenum, titanium, tungsten, tantalum, zirconium, cobalt or hafnium.

As an example, a thickness of the third conductive film is 30˜1500 Å.]

Embodiments of the invention provide a bather layer, a method for fabricating the barrier layer, a TFT and an array substrate. When the barrier layer is applied to a TFT, it can block copper atoms from diffusing to other layers, thereby reducing the harm to the performance of the TFT.

### BRIEF DESCRIPTION OF THE DRAWINGS

In order to clearly illustrate the technical solution of the embodiments of the invention, the drawings of the embodiments will be briefly described in the following. It is obvious that the described drawings are only related to some embodiments of the invention and thus are not limitative of the invention.

FIG. 1 schematically illustrates a configuration of a barrier layer provided by conventional arts;

FIG. 2 schematically illustrates a first configuration of a barrier layer in accordance with an embodiment of the invention;

FIG. 3 schematically illustrates a second configuration of a barrier layer in accordance with an embodiment of the invention;

FIG. 4 schematically illustrates a third configuration of a barrier layer in accordance with an embodiment of the invention;

FIG. 5 schematically illustrates a configuration of a TFT in accordance with an embodiment of the invention;

FIG. 6 schematically illustrates a first configuration of an array substrate in accordance with an embodiment of the invention; and

FIG. 7 schematically illustrates a second configuration of an array substrate in accordance with an embodiment of the invention.

### NUMERAL REFERENCES

10—gate electrode; 20—gate insulation layer; 30—semiconductor active layer; 40—barrier layer; 401—first layer of conductive film; 402—second layer of conductive film; 403—barrier unit; 4031—upper conductive film; 4032—lower conductive film; 404—third layer of conductive film; 50—source/drain metal layer; 501—source electrode; 502—drain electrode; 60—Cu atom; 70—grain boundary; 80—grain boundary filling; 90—pixel electrode; 100—passivation layer; 110—common electrode.

### DETAILED DESCRIPTION

In order to make objects, technical details and advantages of the embodiments of the invention apparent, the technical solutions of the embodiment will be described in a clearly and fully understandable way in connection with the drawings related to the embodiments of the invention. It is obvious that the described embodiments are just a part but not all of the embodiments of the invention. Based on the described embodiments herein, those skilled in the art can obtain other embodiment(s), without any inventive work, which should be within the scope of the invention.

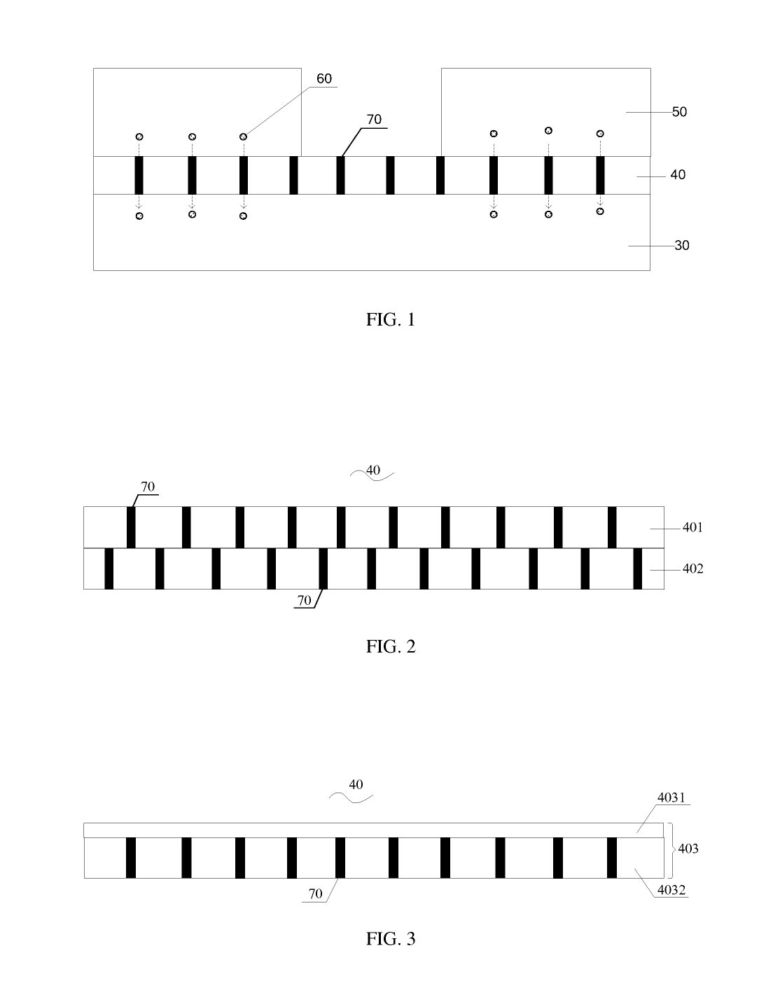

An embodiment of the invention provides a barrier layer 40 as illustrated in FIG. 2; the barrier layer comprises at least two layers of conductive films; grain boundaries 70 in any layer of the conductive films is arranged in a staggered manner relative to grain boundaries 70 in another layer of the conductive films contacting therewith.

It should be noted, firstly, copper is used for metal electrodes in the conventional display field to solve the problem of signal delay, which still has to be solved when the barrier layer provided by the embodiments of the invention is employed in a display comprising a TFT, and therefore the barrier layer still requires a material with low resistivity. Furthermore, as copper is used to fabricate metal electrodes, temperature during the fabrication processes may be as high as 200˜450° C., which means excellent thermal stability is prerequisite for the material used as the barrier layer.

Secondly, the number of layers of the conductive films comprised in the barrier layer 40 will not be limited in the embodiment of the invention. Instead, it may be configured as necessary.

In the bather layer provided by the embodiment of the invention, the grain boundaries 70 of any layer of the conductive films therein is arranged in a staggered manner relative to grain boundaries 70 in another layer of the conductive films contacting therewith. A staggered configuration of grain boundaries is thus formed in a contacting surface between any two contacting layers of the conductive films. The barrier layer, when employed in a TFT having metal electrodes made of copper, can therefore block the diffusion of copper atoms. For example, the barrier layer can block the copper atoms from diffusing to a semiconductor active layer 30, and it in turn reduces the harm to the performance of the TFT device.

Optionally, the at least two layers of conductive films comprise two layers of conductive films, the two layers of conductive films comprise a first layer of conductive film 401 and a second layer of conductive film 402. In this way, the two layers of the conductive films on one hand can prevent the diffusion of the copper atoms, and on the other hand can reduce the number of processes and save cost.

Herein, “a first layer” and “a second layer” are only used to describe names of the conductive films and do not intend to define relative positions of the first layer of the conductive films 401 and the second layer of the conductive films 402. That is, the first layer of the conductive films 401 may be disposed above or below the second layer of the conductive films 402.

Furthermore, when the barrier layer 40 is used in a TFT with metal electrodes made of copper, the resistivity and transparency of the barrier layer 40, and the overall thickness of the TFT influence the performance of the TFT. Therefore, a thickness of any layer of the conductive films is preferably 30˜500 Å.

Herein, the resistivity of the barrier layer increases when the thickness of the barrier layer is too large. Therefore, in the embodiment of the invention, when the barrier layer 40 comprises more than two layers of conductive films, the thickness is preferably less than 1500 Å.

Based on the above, for example, the first layer of the conductive films 401 and the second layer of the conductive films 402 both comprise a metal element with high thermal stability and low resistivity. The metal element having high thermal stability and low resistivity comprises molybdenum (Mo), titanium (Ti), tungsten (W), tantalum (Ta), zirconium (Zr), cobalt (Co) or hafnium (Hf) or the like.

It is noted that herein the metal element having high thermal stability and low resistivity and forming the first layer of the conductive films 401 and the second layer of the conductive film 402 may comprise one metal element described above or different metal elements described above.

By means of the above configuration, a barrier layer 40 with two layers of conductive films having different grain boundary 70 arrangements is obtained. A staggered configuration of grain boundaries 70 is formed in a contacting surface between the two layers of conductive films. When being employed in a TFT have metal electrodes made of copper, the above barrier layer 40 can block the diffusion of copper atoms 60, thereby reducing the harm to the performance of the TFT device. Moreover, since the metal elements molybdenum (Mo), titanium (Ti), tungsten (W), tantalum (Ta), zirconium (Zr), cobalt (Co) or hafnium (Hf) all have relative low resistivity, when being employed in a TFT, the resistance of the metal electrode made of copper will not be much affected as to invoke signal delay problem to a display employing the TFT.

Or, for example, the first layer of the conductive films 401 comprises a metal element having high thermal stability and low resistivity, while the second layer of the conductive films 402 comprises a compound or an alloy formed from the metal element having high thermal stability and low resistivity.

The compound formed from the metal element having high thermal stability and low resistivity comprises oxide, nitride, or oxynitride.

The metal element having high thermal stability and low resistivity comprises molybdenum (Mo), titanium (Ti), tungsten (W), tantalum (Ta), zirconium (Zr), cobalt (Co) or hafnium (Hf). Based on that, the compound formed from the metal element having high thermal stability and low resistivity comprises for example molybdenum oxide, molybdenum nitride, molybdenum oxynitride, tungsten oxide, hafnium oxide, tantalum nitride, or zirconium nitride or the like.

As the metal element molybdenum (Mo), titanium (Ti), tungsten (W), tantalum (Ta), zirconium (Zr), cobalt (Co) or hafnium (Hf) all has relative low resistivity, though the compound or alloy formed therewith has relatively high resistivity, when the metal element and the compound or alloy formed therewith are used to form the barrier layer at the same time, and when the barrier layer is used in a TFT with metal electrodes made of copper, the resistance of the metal electrodes made of copper will not be much affected as to invoke signal delay problem to a display employing the TFT.

In the following three embodiments will be used to describe the above barrier layer in detail but not to limit the invention.

### Embodiment 1

With reference to FIG. 2, the embodiment provides a barrier layer 40, which comprises a first layer of conductive film 401 and a second layer of conductive film 402 contacting each other. A thickness of the first layer of conductive film is 30˜500 Å, and a thickness of the second layer of conductive film is 30˜500 Å. The first layer of conductive film 401 is a conductive film made of metal element Mo, and the second layer of conductive film 402 is a conductive film of molybdenum oxide formed from the metal element Mo. Moreover, grain boundaries 70 of Mo element in the first layer of conductive film 401 and grain boundaries 70 of molybdenum oxide in the second layer of conductive film 402 are arranged in a staggered manner.

Herein, the configuration in which the grain boundaries 70 of Mo element in the first layer of conductive film 401 and the grain boundaries 70 of molybdenum oxide in the second layer of conductive film 402 are arranged in a staggered manner may be implemented in the following way.

For example, a layer of metal element Mo with a thickness of about 30˜500 Å is deposited on a substrate by sputtering or thermal evaporation as the first layer of conductive film 401. By taking the first layer of conductive film 401 as a substrate, oxygen in plasma condition is introduced when metal Mo is sputtered to accordingly form a molybdenum oxide conductive film with a thickness of about 30˜500 Å on the first layer of conductive film 401 as the second layer of conductive film 402. As growth directions of the molybdenum oxide and the metal element Mo are different from each other, the grain boundaries 70 form a staggered configuration at a contacting interface between the first layer of conductive film 401 and the second layer of conductive film 402.

It is noted that when the barrier layer 40 is applied to a TFT having metal electrodes made of copper and the barrier layer is disposed for example between the semiconductor active layer and the source/drain metal layer made of copper, in case that the semiconductor active layer is of a metal oxide semiconductor such as an amorphous Indium Gallium Zinc Oxide (IGZO) active layer, some of the above metal elements such as Mo may react with IGZO, which reaction forms molybdenum oxide at the contacting interface, causing the performance of the TFT to degrade.

Therefore, to solve the problem and keep blocking the diffusion of the copper atoms, the configuration in which the grain boundaries 70 in the first layer of conductive film 401 and the grain boundaries 70 in the second layer of conductive film 402 are arranged in a staggered manner may be implemented in the following way.

When metal Mo is deposited by sputtering or thermal evaporation with the metal oxide semiconductor active layer being used as a substrate, oxygen in plasma condition is introduced, such that a molybdenum oxide conductive film with a thickness of about 30˜500 Å is formed on the metal oxide semiconductor active layer as the second layer of conductive film 402. Then the second layer of conductive film 402 is taken as a substrate to deposit a layer of metal element Mo with a thickness of about 30˜500 Å as the first layer of conductive film 401.

### Embodiment 2

With reference to FIG. 2, the embodiment provides a bather layer 40, which comprises a first layer of conductive film 401 and a second layer of conductive film 402 contacting each other. A thickness of the first layer of conductive film is 30˜500 Å, and a thickness of the second layer of conductive film is 30˜500 Å. Both the first layer of conductive film 401 and the second layer of conductive film 402 are conductive films of Ta element. Moreover, grain boundaries 70 of Ta element in the first layer of conductive film 401 and grain boundaries 70 of Ta element in the second layer of conductive film 402 are arranged in a staggered manner.

Herein, the grain boundaries 70 of Ta element in the first layer of conductive film 401 and the grain boundaries 70 of Ta element in the second layer of conductive film 402 being arranged in a staggered manner may be implemented in the following way.

For example, a layer of metal element Ta with a thickness of about 30˜500 Å is deposited on a substrate by sputtering or thermal evaporation as the first layer of conductive film 401. Taking the first layer of conductive film 401 as a substrate, when sputtering metal Ta, another layer of metal element Ta with a thickness of about 30˜500 Å is formed on the first layer of conductive film 401, by changing process conditions such as sputtering power and film formation speed, as the second layer of conductive film 402.

As the film formation conditions for the first layer of conductive film 401 and the second layer of conductive film 402 both made of metal Ta element are different, accordingly, growth directions of the metal elements Ta in the first layer of conductive film 401 and in the second layer of conductive film 402 are different, producing the grain boundaries at the contacting interface form a staggered configuration.

### Embodiment 3

With reference to FIG. 2, the embodiment provides a barrier layer 40, which comprises a first layer of conductive film 401 and a second layer of conductive film 402 contacting each other. A thickness of the first layer of conductive film is 30˜500 Å, and a thickness of the second layer of conductive film is 30˜500 Å. The first layer of conductive film 401 is a conductive film made of metal element Mo, the second layer of conductive film 402 is a conductive film of Mo—Ti alloy formed from the metal element Mo. Moreover, grain boundaries 70 of Mo element in the first layer of conductive film 401 and grain boundaries 70 of Mo—Ti alloy in the second layer of conductive film 402 are arranged in a staggered manner.

Herein, the configuration in which the grain boundaries 70 of metal element Mo in the first layer of conductive film 401 and the grain boundaries 70 of Mo—Ti alloy in the second layer of conductive film 402 are arranged in a staggered manner may be implemented in the following way.

For example, a layer of metal element Mo with a thickness of about 30˜500 Å is deposited on a substrate by sputtering as the first layer of conductive film 401. By taking the first layer of conductive film 401 as a substrate, sputtering Mo—Ti alloy to form the second layer of conductive film 402 of Mo—Ti alloy with a thickness of about 30˜500 Å on the first layer of conductive film 401.

As growth directions of the first layer of conductive film 401 of metal element Mo and the second layer of conductive film 402 of Mo—Ti alloy are different from each other, the grain boundaries 70 form a staggered configuration at the contacting interface between the first layer of conductive film 401 and the second layer of conductive film 402.

An embodiment of the invention further provides another barrier layer 40 as illustrated in FIG. 3. The barrier layer 40 comprises at least one barrier unit 403; any barrier unit 403 comprises a layer of upper conductive film 4031 and a layer of lower conductive film 4032; the upper conductive film 4031 comprises a grain-boundary-free conductive film.

The following should be noted. Firstly, copper is used as metal electrodes in the conventional display field to solve the problem of signal delay, which still has to be solved when the barrier layer provided by the embodiment of the invention is employed in a display comprising a TFT, and therefore the barrier layer still requires a material with low resistivity. Furthermore, as copper is used to fabricate metal electrodes, temperature during the fabrication processes may be up to 200˜450° C., which means excellent thermal stability is prerequisite for the material used as the barrier layer.

Secondly, the number of barrier units comprised in the barrier layer 40 is not defined in the embodiment of the invention. Instead, it may be configured as necessary.

In the barrier layer provided by the embodiment of the invention, as the upper conductive film 4031 is a grain-boundary-free conductive film, it may cover the grain boundary channels of the lower conductive film 4032. When being employed in a TFT with metal electrodes made of copper, the barrier layer can block the diffusion of copper atoms. For example it can block the copper atoms from diffusing to a semiconductor active layer 30, which in turn reduces the harm to the performance of the TFT device.

Furthermore, when the barrier layer 40 is used in a TFT with metal electrodes made of copper, the resistivity and transparency of the barrier layer 40, and the overall thickness of the TFT will influence the performance of the TFT. Therefore, a thickness of any barrier unit is preferably 30˜300 Å.

Optionally, the lower conductive film 4032 comprises a metal element having high thermal stability and low resistivity, or an alloy formed from the metal element having high thermal stability and low resistivity.

The metal element having high thermal stability and low resistivity comprises molybdenum (Mo), titanium (Ti), tungsten (W), tantalum (Ta), zirconium (Zr), cobalt (Co) or hafnium (Hf). Base on that, the alloy formed from the metal element having high thermal stability and low resistivity may be for example Mo—Ti alloy or Mu-W alloy and the like.

As the upper conductive film 4031 is a grain-boundary-free conductive film, it can cover the grain boundary channels of the lower conductive film 4032. When being employed for a TFT having metal electrodes made of copper; the barrier layer can block diffusion of copper atoms, thereby reducing the harm to the performance of the TFT device. Moreover, since the metal elements molybdenum (Mo), titanium (Ti), tungsten (W), tantalum (Ta), zirconium (Zr), cobalt (Co) or hafnium (Hf) all have relative low resistivity, when being employed in a TFT, the resistance of the metal electrode made of copper will not be much affected as to invoke signal delay problem to a display employing the TFT.

In the following one embodiment will be provided to describe the above barrier layer in detail but not to limit the invention.

### Embodiment 4

As illustrated in FIG. 3, the embodiment provides a barrier layer 40, which comprises a barrier unit 403, and a thickness of the barrier unit 403 is 30˜300 Å. The barrier unit 403 comprises a grain-boundary-free upper conductive film 4031 and a lower conductive film 4032 of metal element Zr.

Herein, the barrier unit 403 may be for example implemented in the following way. As an example, metal element Zr is deposited on a substrate by sputtering as the lower conductive film 4032; nitrogen under plasma condition is introduced to a surface of the lower conductive film 4032 of metal element Zr; Zr atoms at the surface of the lower conductive film 4032 react with nitrogen under plasma condition to form the grain-boundary-free upper conductive film 4031.

It is noted that the above procedure may be repeated for multiple times to eventually obtain a barrier layer 40 comprising a plurality of barrier units 403. When the barrier layer 40 comprising the plurality of barrier units 403 is applied to a TFT having metal electrodes made of copper, in considering that the resistance and transparency of the barrier layer 40, and the overall thickness of the TFT will influence the performance of the TFT, a thickness of the eventually formed barrier layer 40 with the plurality of barrier units 403 should be less than or equal to 1500 Å, so as to guarantee the transparency and low resistivity of the barrier layer 40.

As the upper conductive film 4031 is a grain-boundary-free conductive film, it can cover the lower conductive film 4032 and insulate the lower conductive film 4032 from the electrodes comprising copper, thereby preventing the diffusion of copper atoms 60.

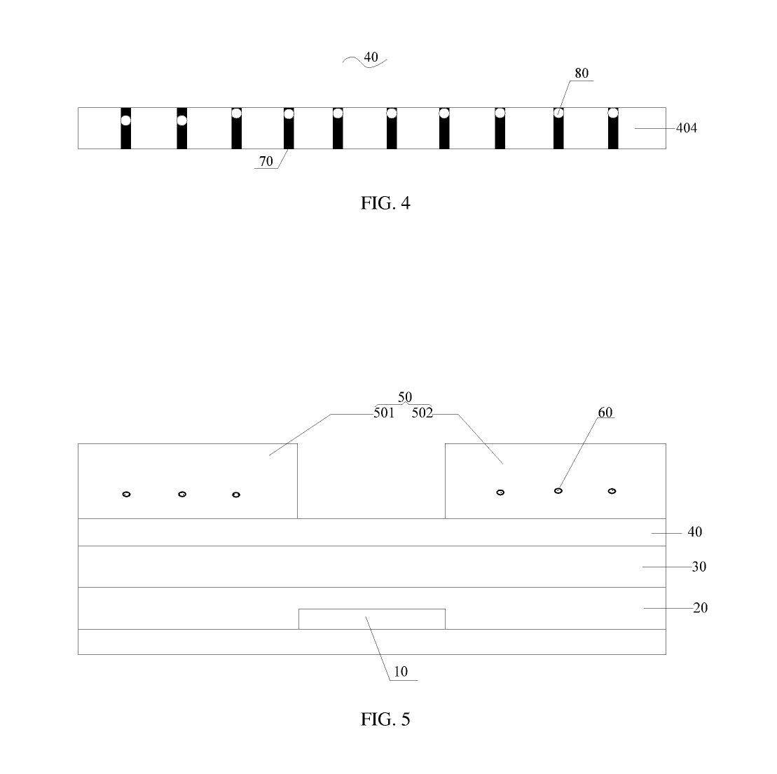

As illustrated in FIG. 4, an embodiment of the invention further provides another barrier layer 40, which comprises a third conductive film 404 having grain boundaries; the barrier layer 40 further comprises grain boundary blockages 80 at the grain boundaries 70 of the third conductive film 404, the grain boundary blockages 80 are configured for filling the grain boundaries of the third conductive film.

To solve the problem of signal delay, the barrier layer requires a material with low resistivity. Moreover, as copper is used to fabricate the metal electrode, temperature during the fabrication processes may be up to 200˜450° C., which means excellent thermal stability, is prerequisite for the material used as the barrier layer.

The barrier layer provided by the embodiment of the invention fills the grain boundaries 70 of the third conductive film 404 by disposing the grain boundary blockages 80 at the grain boundaries 70 of the third conductive film. As a result, when the barrier layer is applied to a TFT having metal electrode made of copper, the diffusion of the copper atoms 60 may be blocked. For example, the grain boundary blockages 80 can block the copper atoms 60 from diffusing to a semiconductor active layer 30, which in turn reduces the harm to the performance of the TFT device.

Furthermore, when the barrier layer 40 is used in a TFT with metal electrodes made of copper, the resistivity and transparency of the barrier layer 40, as well as the overall thickness of the TFT will influence the performance of the TFT. Therefore, a thickness of the third conductive film 404 is preferably 30˜1500 Å.

Optionally, the third conductive film 404 comprises a metal element having high thermal stability and low resistivity, or an alloy formed from the metal element having high thermal stability and low resistivity. The grain boundary blockage comprises oxide, nitride, or oxynitride formed from the metal element having high thermal stability and low resistivity.

The metal element having high thermal stability and low resistivity comprises molybdenum (Mo), titanium (Ti), tungsten (W), tantalum (Ta), zirconium (Zr), cobalt (Co) or hafnium (Hf). Based on that, the oxide, nitride, or oxynitride formed from the metal element having high thermal stability and low resistivity may be for example molybdenum oxide, molybdenum nitride, molybdenum oxynitride, tungsten oxide, hafnium oxide, tantalum nitride, or zirconium nitride or the like.

As the metal element molybdenum (Mo), titanium (Ti), tungsten (W), tantalum (Ta), zirconium (Zr), cobalt (Co) or hafnium (Hf) all has relative low resistivity, when being used in a TFT, the resistance of the metal electrode made of copper will not be much affected as to invoke signal delay problem to a display employing the TFT.

In the following one embodiment will be used to describe the above barrier layer in detail but not to limit the invention.

### Embodiment 5

As illustrated in FIG. 4, the embodiment provides a barrier layer 40, which comprises a third conductive film 404 made of metal element Hf, a thickness of the third conductive film 404 is 30˜1500 Å. The barrier layer 40 further comprises grain boundary blockages 80 at the grain boundaries 70 of the third conductive film 404, and the grain boundary blockages 80 are oxynitride of the metal element Hf, that is hafnium oxynitride, and is configured for filling the grain boundaries 70 of the third conductive film 404.

Herein, comprising the grain boundary blockages 80 at the grain boundaries 70 of the third conductive film 404 may be implemented in the following way.

For example, the metal element Hf is deposited on a substrate by sputtering or thermal evaporation as the third conductive film 404; a mixture of nitrogen and oxygen under plasma condition is introduced to a surface of the third conductive film 404 of the metal element Hf; hafnium atoms at the surface of the third conductive film 404 react with the mixture of nitrogen and oxygen under plasma condition to form the grain boundary blockages 80 of hafnium oxynitride. The grain boundary blockages 80 of hafnium oxynitride can be driven by the high-speed mixture of nitrogen and oxygen under plasma condition to migrate to the grain boundaries 70 at the surface of the third conductive film 404, and block the grain boundaries 70. As a result, when the bather layer 40 is applied to a TFT having metal electrodes made of copper, it can prevent the diffusion of copper atoms 60 to the semiconductor active layer 30, thereby reducing the harm to the performance of the TFT device.

As illustrated in FIG. 5, an embodiment of the invention further provides a TFT, which comprises a gate electrode 10, a gate insulation layer 20, a semiconductor active layer 30, a source/drain metal layer 50 and further any of the above barrier layers 40.

As illustrated in FIG. 5, when the material of the source/drain metal layer 50 is copper, the barrier layer 40 is disposed between the source/drain metal layer 50 and the semiconductor active layer 30. It can be contemplated that the barrier layer 40 may also be disposed between the gate electrode 10 and the gate insulation layer 20 when the material of the gate electrode 10 is also copper.

As for the barrier layer 40, with reference to FIG. 2, the barrier layer 40 may optionally comprise at least two layers of conductive films; grain boundaries 70 in any layer of the conductive films is arranged in a staggered manner relative to grain boundaries 70 in another layer of the conductive films contacting therewith.

Please note that, firstly, to solve the problem of signal delay, the barrier layer requires a material with low resistivity. Moreover, as copper is used to fabricate the metal electrode, temperature during the fabrication processes may be up to 200˜450° C., which means excellent thermal stability is prerequisite for the material used as the barrier layer.

Secondly, the number of layers of conductive films comprised in the barrier layer 40 will not be limited in the embodiment of the invention. Instead, it may be configured as necessary.

In the TFT provided by the embodiment of the invention, the grain boundaries 70 of any layer of conductive films comprised in the bather layer 40 is arranged in a staggered manner relative to grain boundaries 70 in another layer of the conductive films contacting therewith. A staggered configuration of grain boundaries is thus formed in a contacting surface between any two layers of conductive films that contact with each other. The barrier layer, when being employed in a TFT having metal electrodes made of copper, can therefore block the diffusion of copper atoms. For example, it can block the copper atoms from diffusing to a semiconductor active layer 30, which in turn reduces the harm to the performance of the TFT device.

Optionally, the at least two layers of conductive films comprises two layers of conductive films, and the two layers of conductive films comprises a first layer of conductive film 401 and a second layer of conductive film 402. In this fashion, the two layers of conductive films on one hand can prevent the diffusion of the copper atoms, and on the other hand can reduce the number of processes and save cost.

Herein, “a first layer” and “a second layer” are only used to describe names of the conductive films and do not limit relation positions of the first layer of conductive film 401 and the second layer of conductive film 402. That is, the first layer of conductive film 401 may be disposed above or below the second layer of conductive film 402.

Furthermore, when the barrier layer 40 is used in a TFT with metal electrodes made of copper, the resistivity and transparency of the barrier layer 40 as well as the overall thickness of the TFT will influence the performance of the TFT. Therefore, a thickness of any layer of the conductive films is preferably 30˜500 Å.

Herein, the resistivity of the barrier layer will increase when the thickness of the barrier layer is too large. Therefore, in the embodiment of the invention, when the barrier layer 40 comprises more than two layers of conductive films, the thickness is preferably less than 1500 Å.

Based on the above, for example, the first layer of conductive film 401 and the second layer of conductive film 402 both comprise metal elements with high thermal stability and low resistivity. The metal element having high thermal stability and low resistivity comprises molybdenum (Mo), titanium (Ti), tungsten (W), tantalum (Ta), zirconium (Zr), cobalt (Co) or hafnium (Hf) or the like.

It is noted that herein the metal element having high thermal stability and low resistivity and forming the first layer of conductive film 401 and the second layer of conductive film 402 may comprise one metal element described above or different metal elements described above.

By means of the above configuration, a barrier layer 40 comprising two layers of conductive films having different grain boundary 70 arrangements is obtained. A staggered configuration of the grain boundaries 70 is formed in a contacting surface between the two layers of conductive films. When being employed in a TFT having metal electrodes made of copper, the above barrier layer 40 can block the diffusion of copper atoms 60, thereby reducing the harm to the performance of the TFT device. Moreover, since the metal elements molybdenum (Mo), titanium (Ti), tungsten (W), tantalum (Ta), zirconium (Zr), cobalt (Co) or hafnium (Hf) all have relative low resistivity, when being employed in a TFT, the resistance of the metal electrode made of copper will not be much affected as to invoke signal delay problem to a display employing the TFT.

Or, for example, the first layer of conductive film 401 comprises a metal element having high thermal stability and low resistivity, while the second layer of conductive film 402 comprises a compound or an alloy formed from the metal element having high thermal stability and low resistivity.

The compound formed from the metal element having high thermal stability and low resistivity comprises oxide, nitride, or oxynitride.

The metal element having high thermal stability and low resistivity comprises molybdenum (Mo), titanium (Ti), tungsten (W), tantalum (Ta), zirconium (Zr), cobalt (Co) or hafnium (Hf). Based on that, the compound formed from the metal element having high thermal stability and low resistivity comprises for example molybdenum oxide, molybdenum nitride, molybdenum oxynitride, tungsten oxide, hafnium oxide, tantalum nitride, or zirconium nitride or the like.

As the metal element molybdenum (Mo), titanium (Ti), tungsten (W), tantalum (Ta), zirconium (Zr), cobalt (Co) or hafnium (Hf) all has relative low resistivity, though the compound or alloy formed therewith has relatively high resistivity, when the metal element and the compound or alloy formed therewith are used to formed the barrier layer at the same time, and when the barrier layer is used in a TFT having metal electrodes made of copper, the resistance of the metal electrodes made of copper will not be much affected as to invoke signal delay problem to a display employing the TFT.

In the following, three exemplary TFTs will be provided to describe the above TFTs and the barrier layer 40 in detail but not to limit the invention.

### Example 1

With reference to FIG. 5, the example provides a TFT, which comprises a gate electrode 10, a gate insulation layer 20, a semiconductor active layer 30, and a source/drain metal layer 50, and a material of the source/drain metal layer 50 is copper; the barrier layer 40 is disposed between the source/drain metal layer 50 and the semiconductor active layer 30.

With reference to FIG. 2, the barrier layer 40 comprises a first layer of conductive film 401 and a second layer of conductive film 402 contacting each other. A thickness of the first layer of conductive film is 30˜500 Å, and a thickness of the second layer of conductive film is 30˜500 Å. The first layer of conductive film 401 is a conductive film made of metal element Mo, and the second layer of conductive film 402 is a conductive film of molybdenum oxide formed from the metal element Mo. Moreover, grain boundaries 70 of Mo element in the first layer of conductive film 401 and grain boundaries 70 of molybdenum oxide in the second layer of conductive film 402 are arranged in a staggered manner.

Herein, the configuration in which the grain boundaries 70 of Mo element in the first layer of conductive film 401 and the grain boundaries 70 of molybdenum oxides in the second layer of conductive film 402 are arranged in a staggered manner may be implemented in the following way. For example, a layer of metal element Mo with a thickness of about 30˜500 Å is deposited on a substrate by sputtering or thermal evaporation as the first layer of conductive film 401. By taking the first layer of conductive film 402 as a substrate, oxygen in plasma condition is introduced when sputtering metal Mo to accordingly form a molybdenum oxide conductive film with a thickness of about 30˜500 Å on the first layer of conductive film 401 as the second layer of conductive film 402.

As growth directions of the molybdenum oxide and the metal element Mo are different from each other, the grain boundaries 70 form a staggered configuration at the contacting interface between the first layer of conductive film 401 and the second layer of conductive film 402.

It is noted that when the barrier layer 40 is applied to a TFT having a source/drain metal electrode made of copper, and a semiconductor active layer is a metal oxide semiconductor, such as amorphous Indium Gallium Zinc Oxide (IGZO) active layer, some of the above metal elements such as Mo may react with IGZO, which will form molybdenum oxide at the contacting interface, causing the performance of the TFT to degrade.

To solve the problem and keep blocking the diffusion of the copper atoms, the configuration in which the grain boundaries 70 of the Mo element in the first layer of conductive film 401 and the grain boundaries 70 of the molybdenum oxide in the second layer of conductive film 402 are arranged in a staggered manner may be implemented in the following way. For example, when depositing metal Mo with the metal oxide semiconductor active layer as a substrate by sputtering or thermal evaporation, oxygen in plasma condition is introduced, such that a molybdenum oxide conductive film with a thickness of about 30˜500 Å is formed on the metal oxide semiconductor active layer as the second layer of conductive film 402. Then the second layer of conductive film 402 is taken as a substrate to deposit a layer of metal element Mo with a thickness of about 30˜500 Å as the first layer of conductive film 401.

### Example 2

With reference to FIG. 5, the example provides a TFT, which comprises a gate electrode 10, a gate insulation layer 20, a semiconductor active layer 30, and a source/drain metal layer 50, a material of the source/drain metal layer 50 is copper, and the barrier layer 40 is disposed between the source/drain metal layer 50 and the semiconductor active layer 30.

With reference to FIG. 2, the barrier layer 40 comprises a first layer of conductive film 401 and a second layer of conductive film 402 contacting each other; a thickness of the first layer of conductive film is 30˜500 Å, and a thickness of the second layer of conductive film is 30˜500 Å. Both the first layer of conductive film 401 and the second layer of conductive film 402 are conductive films of Ta element. Moreover, grain boundaries 70 of Ta element in the first layer of conductive film 401 and grain boundaries 70 of Ta element in the second layer of conductive film 402 are arranged in a staggered manner.

Herein, the configuration in which the grain boundaries 70 of Ta element in the first layer of conductive film 401 and the grain boundaries 70 of Ta element in the second layer of conductive film 402 are arranged in a staggered manner may be implemented in the following way. For example, a layer of metal element Ta with a thickness of about 30˜500 Å is deposited on a substrate by sputtering or thermal evaporation as the first layer of conductive film 401. Taking the first layer of conductive film 401 as a substrate, when sputtering metal Ta, another layer of metal element Ta with a thickness of about 30˜500 Å is formed on the first layer of conductive film 401, by changing process conditions such as sputtering power and film formation speed, as the second layer of conductive film 402.

As the film formation conditions for the first layer of conductive film 401 and the second layer of conductive film 402 both made of metal Ta element are different, accordingly, growth directions of the metal element Ta in the first layer of conductive film 401 and in the second layer of conductive film 402 are different from each other, which makes the grain boundaries at the contacting interface form a staggered configuration.

### Example 3

With reference to FIG. 5, the example provides a TFT, which comprises a gate electrode 10, a gate insulation layer 20, a semiconductor active layer 30, and a source/drain metal layer 50, a material of the source/drain metal layer 50 is copper, and the barrier layer 40 is disposed between the source/drain metal layer 50 and the semiconductor active layer 30.

With reference to FIG. 2, the barrier layer 40 comprises a first layer of conductive film 401 and a second layer of conductive film 402 contacting each other. A thickness of the first layer of conductive film is 30˜500 Å, and a thickness of the second layer of conductive film is 30˜500 Å. The first layer of conductive film 401 is a conductive film made of metal element Mo, and the second layer of conductive film 402 is a conductive film of Mo—Ti alloy formed from metal Mo. Moreover, grain boundaries 70 of Mo element in the first layer of conductive film 401 and grain boundaries 70 of Mo—Ti alloy in the second layer of conductive film 402 are arranged in a staggered manner.

Herein, the configuration in which the grain boundaries 70 of metal element Mo in the first layer of conductive film 401 and the grain boundaries 70 of Mo—Ti alloy in the second layer of conductive film 402 are arranged in a staggered manner may be implemented in the following way. For example, a layer of metal element Mo with a thickness of about 30˜500 Å is deposited on a substrate by sputtering as the first layer of conductive film 401. By taking the first layer of conductive film 401 as a substrate, Mo—Ti alloyed is further sputtered to form the second layer of conductive film 402 of Mo—Ti alloy with the thickness of about 30˜500 Å on the first layer of conductive film 401.

As growth directions of the first layer of conductive film 401 of metal Mo element and the second layer of conductive film 402 of Mo—Ti alloy are different from each other, the grain boundaries 70 form a staggered configuration at the contacting interface between the first layer of conductive film 401 and the second layer of conductive film 402.

As illustrated in FIG. 3, the barrier layer 40 optionally comprises at least one barrier unit 403; any barrier unit 403 comprises a layer of upper conductive film 4031 and a layer of lower conductive film 4032; the upper conductive film 4031 comprises a grain-boundary-free conductive film.

Please note that, firstly, to solve the problem of signal delay, the barrier layer requires a material with low resistivity. Moreover, as copper is used to fabricate the metal electrode, temperature during the fabrication processes may be up to 200˜450° C., which means excellent thermal stability is prerequisite for the material used as the barrier layer.

Secondly, the number of barrier units comprised in the bather layer 40 will not be limited in the embodiment of the invention. Instead, it may be configured as necessary.

In the TFT provided by the embodiment of the invention, as the upper conductive film 4031 comprised in the barrier layer 40 therein is a grain-boundary-free conductive film, it can cover the grain boundary channels of the lower conductive film 4032. When being employed in a TFT having metal electrodes made of copper, the barrier layer can block the diffusion of the copper atoms 60, which in turn reduces the harm to the performance of the TFT device.

Furthermore, when the barrier layer 40 is used in a TFT with metal electrodes made of copper, the resistivity and transparency of the barrier layer 40 as well as the overall thickness of the TFT will influence the performance of the TFT. Therefore, a thickness of any barrier unit is preferably 30˜300 Å.

Optionally, the lower conductive film 4032 comprises a metal element having high thermal stability and low resistivity, or an alloy formed from the metal element having high thermal stability and low resistivity.

The metal element having high thermal stability and low resistivity comprises molybdenum (Mo), titanium (Ti), tungsten (W), tantalum (Ta), zirconium (Zr), cobalt (Co) or hafnium (Hf). Base on that, the alloy formed from the metal element having high thermal stability and low resistivity may be for example Mo—Ti alloy or Mu-W alloy or the like.

As the upper conductive film 4031 is a grain-boundary-free conductive film, it can cover the grain boundary channels of the lower conductive film 4032. When being applied to a TFT having metal electrodes made of copper, the barrier layer 40 can block diffusion of copper atoms 60, thereby reducing the harm to the performance of the TFT device. Moreover, since the metal elements molybdenum (Mo), titanium (Ti), tungsten (W), tantalum (Ta), zirconium (Zr), cobalt (Co) or hafnium (Hf) all have relative low resistivity, when being employed in a TFT, the resistance of the metal electrode made of copper will not be much affected as to invoke the signal delay problem to a display employing the TFT.

In the following, one exemplary TFT will be provided to describe the above TFT and the barrier layer 40 in detail but not to limit the invention.

### Example 4

With reference to FIG. 5, the example provides a TFT, which comprises a gate electrode 10, a gate insulation layer 20, a semiconductor active layer 30, and a source/drain metal layer 50, a material of the source/drain metal layer 50 is copper, and the barrier layer 40 is disposed between the source/drain metal layer 50 and the semiconductor active layer 30.

As illustrated in FIG. 3, the barrier layer 40 comprises a barrier unit 403, and a thickness of the barrier unit 403 is 30˜300 Å. The barrier unit 403 comprises a grain-boundary-free upper conductive film 4031 and a lower conductive film 4032 of metal element zirconium.

Herein, the barrier unit 403 may be for example implemented in the following way. As an example, metal element Zr is deposited on a substrate by sputtering as the lower conductive film 4032; nitrogen under plasma condition is introduced to a surface of the lower conductive film 4032 of metal element Zr; Zr atoms at the surface of the lower conductive film 4032 react with nitrogen under plasma condition to form the layer of grain-boundary-free upper conductive film 4031.

It is noted that the above procedure may be repeated for many times to eventually obtain a barrier layer 40 comprising a plurality of barrier units 403. When the barrier layer 40 comprising the plurality of barrier units 403 is applied to a TFT having metal electrodes made of copper, in considering that the resistivity and transparency of the barrier layer 40 as well as the overall thickness of the TFT will influence the performance of the TFT, a thickness of the eventually formed barrier layer 40 with the plurality of barrier units 403 should be less than or equal to 1500 Å, so as to guarantee the transparency and low resistivity of the barrier layer 40.

As the upper conductive film 4031 is a grain-boundary-free conductive film, it can cover the lower conductive film 4032 and insulate the lower conductive film 4032 from the electrodes comprising copper, thereby preventing the diffusion of copper atoms 60.

As illustrated in FIG. 4, the barrier layer 40 optionally comprises a third conductive film 404 having grain boundaries; the barrier layer 40 further comprises grain boundary blockages 80 at the grain boundaries 70 of the third conductive film, the grain boundary blockages 80 are configured for filling the grain boundaries of the third conductive film.

Please note that, to solve the problem of signal delay, the barrier layer requires a material with low resistivity. Moreover, as copper is used to fabricate the metal electrode, temperature during the fabrication processes may be up to 200˜450° C., which means excellent thermal stability is prerequisite for the material used as the barrier layer.

In the TFT provided by the embodiment of the invention, the barrier layer 40 therein comprises the layer of third conductive film 404 having grain boundaries and further comprises the grain boundary blockages 80 at the grain boundaries 70 of the third conductive film 404. Therefore, the grain boundaries 70 of the third conductive film 404 are filled by disposing the grain boundary blockages 80 at the grain boundaries 70 of the third conductive film. As a result, when the barrier layer is applied to a TFT having metal electrodes made of copper, the diffusion of copper atoms 60 may be blocked. For example, it can block the copper atoms 60 from diffusing to the semiconductor active layer 30, which in turn reduces the harm to the performance of the TFT device.

Furthermore, when the barrier layer 40 is used in a TFT with metal electrodes made of copper, the resistivity and transparency of the barrier layer 40 as well as the overall thickness of the TFT will influence the performance of the TFT. Therefore, a thickness of the third conductive film is preferably 30˜1500 Å.

For example, the third conductive film 404 comprises a metal element having high thermal stability and low resistivity, or an alloy formed from the metal element having high thermal stability and low resistivity. The grain boundary blockages comprise oxide, nitride, or oxynitride formed from the metal element having high thermal stability and low resistivity.

The metal element having high thermal stability and low resistivity comprises molybdenum (Mo), titanium (Ti), tungsten (W), tantalum (Ta), zirconium (Zr), cobalt (Co) or hafnium (Hf) or the like. Based on that, the oxide, nitride, or oxynitride formed from the metal element having high thermal stability and low resistivity may be for example molybdenum oxide, molybdenum nitride, molybdenum oxynitride, tungsten oxide, hafnium oxide, tantalum nitride, or zirconium nitride or the like.

As the metal element molybdenum (Mo), titanium (Ti), tungsten (W), tantalum (Ta), zirconium (Zr), cobalt (Co) or hafnium (Hf) all has relative low resistivity, when being used in a TFT, the resistance of the metal electrode made of copper will not be much affected as to invoke signal delay problem to a display employing the TFT.

In the following, one exemplary TFT will be provided to describe the above TFT and the barrier layer in detail but not to limit the invention.

### Example 5

With reference to FIG. 5, the example provides a TFT, which comprises a gate electrode 10, a gate insulation layer 20, a semiconductor active layer 30, and a source/drain metal layer 50, a material of the source/drain metal layer 50 is copper, and the barrier layer 40 is disposed between the source/drain metal layer 50 and the semiconductor active layer 30.

As illustrated in FIG. 4, the barrier layer 40 comprises a third conductive film 404 made of metal element Hf, and a thickness of the third conductive film 404 is 30˜1500 Å. The barrier layer 40 further comprises grain boundary blockages 80 at grain boundaries 70 of the third conductive film 404, the grain boundary blockages 80 are oxynitride of the metal element Hf, that is hafnium oxynitride, and are configured for filling the grain boundaries 70 of the third conductive film 404 made of the metal element Hf.

Herein, the grain boundary blockages 80 provided at the grain boundaries 70 of the third conductive film 404 made of the metal element Hf may be implemented in the following way. For example, the metal element Hf is deposited on a substrate by sputtering or thermal evaporation as the third conductive film 404; a mixture of nitrogen and oxygen under plasma condition is introduced to a surface of the third conductive film 404 of the metal element Hf; hafnium atoms at the surface of the third conductive film 404 react with the mixture of nitrogen and oxygen under plasma condition to form the grain boundary blockages 80 of hafnium oxynitride. The grain boundary blockages 80 of hafnium oxynitride can migrate to the grain boundaries 70 at the surface of the third conductive film, driven by the high-speed mixture of nitrogen and oxygen under plasma condition, and block the grain boundaries 70. As a result, when the bather layer 40 is applied to a TFT having metal electrodes made of copper, it can prevent the copper atoms 60 from diffusing to the semiconductor active layer 30, thereby reducing the harm to the performance of the TFT device.

It is noted that oxide semiconductors, among which IGZO is a typical one, have been widely used in the field of display technologies as semiconductor active layers in TFTs for the advantages of high electron mobility and good uniformity. However, some of the above metal elements such as Mo will react with IGZO, forming molybdenum oxide and degrading the performance of the TFTs. In this case, the portion of the bather layer 40 contacting the semiconductor active layer should be made of a material not reactive with IGZO.

It is noted that the above examples are described with reference to bottom-gate TFTs. However, TFTs of the invention are not limited to that, but can be for example top-gate TFTs or dual-gate TFTs.

Furthermore, an embodiment of the invention further provides an array substrate, comprising a substrate and a TFT disposed on the substrate; the TFT is one of the above-mentioned TFTs. It can be contemplated that the array substrate further comprises a pixel electrode, or comprises a pixel electrode and a common electrode.

Based on the above barrier layers, an embodiment of the invention further provides a method for fabricating a barrier layer 40. The method comprises: forming at least two layers of conductive films on a base substrate; grain boundaries 70 in any layer of the conductive films is arranged in a staggered manner relative to grain boundaries 70 in another layer of conductive films contacting therewith.

As the configuration of any layer of the conductive films is different from that of another layer of the conductive films contacting therewith, growth directions of grains forming the conductive films are different from each other, thereby forming a staggered configuration for the grain boundaries 70 at a contacting interface between the at least two layers of conductive films. When the barrier layer is applied to a TFT having metal electrodes made of copper, it can block copper atoms from diffusing to the semiconductor active layer 30, which in turn reduces the harm to the performance of the TFT device.

Optionally, at least two layers of conductive films are formed on the base substrate, which are respectively a first layer of conductive film 401 and a second layer of conductive film 402. Both the first layer of conductive film 401 and the second layer of conductive film 402 comprise metal elements having high thermal stability and low resistivity. The metal element having high thermal stability and low resistivity comprises molybdenum (Mo), titanium (Ti), tungsten (W), tantalum (Ta), zirconium (Zr), cobalt (Co) or hafnium (Hf). For the fabrication method, Embodiment 2 of the invention can be referred to, and the method will not be elaborated here again.

Or, optionally, at least two layers of conductive films are formed on the base substrate, which are respectively a first layer of conductive film 401 and a second layer of conductive film 402. The first conductive film 401 comprises a metal element having high thermal stability and low resistivity, while the second conductive film 402 comprises a compound or an alloy formed from the metal element having high thermal stability and low resistivity. The metal element having high thermal stability and low resistivity comprises molybdenum (Mo), titanium (Ti), tungsten (W), tantalum (Ta), zirconium (Zr), cobalt (Co) or hafnium (Hf), and the compound comprises oxide, nitride, or oxynitride formed from the above metal elements. For the fabrication method, Embodiment 1 or 3 of the invention can be referred to, and the method will not be elaborated here again.

Furthermore, when the barrier layer 40 is used in a TFT with metal electrodes made of copper, the resistivity and transparency of the barrier layer 40 as well as the overall thickness of the TFT will influence the performance of the TFT. Therefore, a thickness of the first layer of the conductive film 401 is preferably 30˜500 Å; and a thickness of the second layer of the conductive film 402 is preferably 30˜500 Å.

An embodiment of the invention provides a method for fabricating a barrier layer 40; the method comprises: forming at least a barrier unit 403 on a base substrate, any barrier unit comprises a layer of upper conductive film layer 4031 and a layer of lower conductive film layer 4032; and the upper conductive film layer 4031 comprises a grain-boundary-free conductive film.

The upper conductive film 4031 is a grain-boundary-free conductive film, and it can cover the lower conductive film 4032. Therefore, when the barrier layer 40 is applied to a TFT having metal electrodes made of copper, it can prevent copper atoms 60 from diffusing to the semiconductor active layer 30, which in turn reduces the harm to the performance of the TFT device.

Optionally, an example of the method comprises forming a lower conductive film 4032 on the base substrate, the low conductive film 4032 comprises a metal element having high thermal stability and low resistivity or an alloy formed from the metal element having high thermal stability and low resistivity; the metal element having high thermal stability and low resistivity comprises molybdenum, titanium, tungsten, tantalum, zirconium, cobalt or hafnium; the alloy for example comprises Mo—Ti alloy or Mo—W alloy.

The method further comprises introducing oxygen, or nitrogen or a mixture of oxygen and nitrogen to a surface of the lower conductive film 4032 that faces the base substrate to form the upper conductive film 4031, and the upper conductive film 4031 is a grain-boundary-free conductive film.

Furthermore, when the barrier layer 40 is used in a TFT with metal electrodes made of copper, and the resistivity and transparency of the barrier layer 40 as well as the overall thickness of the TFT will influence the performance of the TFT. Therefore, a thickness of any of the barrier units is preferably 30˜300 Å

The method for fabricating the barrier layer 40 provided by the embodiment of the invention can be referred to Embodiment 4 of the invention for detail, which will not be elaborated here.

Furthermore, an embodiment of the invention further provides a method for fabricating a barrier layer 40; the method comprises forming a third conductive film 404 having grain boundaries on a base substrate, and forming grain boundary blockages 80 at the grain boundaries 70 of the third conductive film 404. The grain boundary blockages 80 are configured for filling the grain boundaries 70 of the third conductive film 404.

When the barrier layer 40 is applied to a TFT having metal electrodes made of copper, it can prevent copper atoms 60 from diffusing to the semiconductor active layer 30, which in turn reduces the harm to the performance of the TFT device.

Optionally, an example of the method comprises: forming a third conductive film 404 having grain boundaries 70 on a base substrate; the third conductive film 404 comprises a metal element having high thermal stability and low resistivity or an alloy formed from the metal element having high thermal stability and low resistivity. The metal element having high thermal stability and low resistivity comprises molybdenum, titanium, tungsten, tantalum, zirconium, cobalt or hafnium.

The method further comprises introducing oxygen, or nitrogen or a mixture of oxygen and nitrogen to a surface of the third conductive film 404 that faces the base substrate to form the grain boundary blockages 80 at the grain boundaries 70 of the third conductive film 404, and the grain boundary blockages 80 are configured for filling the grain boundaries 70 of the third conductive film 404; the grain boundary blockages 80 comprise oxide, nitride, or oxynitride formed from the metal element having high thermal stability and low resistivity.

Furthermore, when the barrier layer 40 is used in a TFT with metal electrodes made of copper, and the resistivity and transparency of the barrier layer 40 as well as the overall thickness of the TFT will influence the performance of the TFT. Therefore, a thickness of any of the barrier units is preferably 30˜1500 Å

The invention for detail of the method for fabricating the barrier layer 40 provided by the embodiment of the invention can be referred to Embodiment 5, which will not be elaborated here.

Based on the above TFTs, the invention further provides a method for fabricating the above TFTs. The fabrication method comprises the following steps.

S101: forming a layer of Mo metal film on a base substrate and forming a gate electrode 10 on the substrate through one patterning process.

For example, a Mo metal film with a thickness of 1000˜7000 Å may be fabricated on the base substrate by magnetron sputtering. Then the gate electrode 10 is formed on a certain region of the substrate by patterning processes such as exposing, developing, etching, peeling and the like, by using a mask plate. A gate line, a gate line lead and the like are formed at the same time.

S102: forming a gate insulation layer 20 on the substrate after step S101.

For example, a layer of gate insulation layer film with a thickness of about 1000˜6000 Å is formed on the substrate having the gate electrode 10 formed thereon by chemical evaporation deposition (CVD). A material of the gate insulation layer film is normally silicon nitride, and it may also be silicon oxide or silicon oxynitride.

S103: forming a semiconductor active layer film on the substrate after step S102, forming a semiconductor active layer 30 through one patterning process.

For example, a layer of metal oxide semiconductor film such as IGZO film with a thickness of 1000˜6000 Å is formed on the substrate by CVD, then the semiconductor active layer 30 is formed above the gate electrode 10 at a certain region of the substrate by patterning processes such as exposing, developing, etching, peeling, by using a mask plate.

S104: forming a barrier layer film on the substrate after step S103, and forming a barrier layer 40 on the semiconductor active layer 30 through one patterning process.

The barrier layer film may be formed through the following three methods, which are not intended to limit the invention.

Method 1

With reference to FIG. 2, the barrier layer film comprises a first layer of conductive film 401 and a second layer of conductive film 402 contacting each other. A thickness of the first layer of conductive film is 30˜500 Å, and a thickness of the second layer of conductive film is 30˜500 Å. The first layer of conductive film 401 is a conductive film made of metal element Mo, and the second layer of conductive film 402 is a conductive film of molybdenum oxide formed from the metal element Mo. The second conductive film 402 is formed adjacent to the semiconductor active layer 30, and the first layer of conductive film 401 is formed above the second layer of conductive film 402. Moreover, grain boundaries 70 of Mo element in the first layer of conductive film 401 and grain boundaries 70 of molybdenum oxide in the second layer of conductive film 402 are arranged in a staggered manner.

Herein, the configuration of the grain boundaries 70 of metal element Mo in the first layer of conductive film 401 and the grain boundaries 70 of molybdenum oxide in the second layer of conductive film 402 are arranged in a staggered manner may be implemented in the following way. That is, by taking the metal oxide semiconductor active layer as a substrate, oxygen in plasma condition is introduced, when sputtering metal Mo, to form a molybdenum oxide conductive film with a thickness of about 30˜500 Å on the metal oxide semiconductor active layer as the second layer of conductive film 402. Then taking the second conductive film 402 as a substrate, a layer of metal Mo element with a thickness of 30˜500 Å is deposited as the first layer of conductive film 401.

As growth directions of molybdenum oxide and the metal element Mo are different from each other, the grain boundaries 70 form a staggered configuration at a contacting interface between the first layer of conductive film 401 and the second layer of conductive film 402.

Method 2

With reference to FIG. 3, the barrier layer film comprises a layer of upper conductive film 4031 having no grain boundaries and a layer of lower conductive film 4032 of metal Zr element; thicknesses of both layers are 30˜300 Å.

Herein, the barrier layer film may be implemented for example in the following way. For example, a layer of metal element Zr is deposited on a substrate by sputtering as the lower conductive film 4032. Nitrogen under plasma condition is introduced to a surface of the lower conductive film 4032 of metal element Zr; Zr atoms at the surface of the lower conductive film 4032 react with nitrogen under plasma condition to form the grain-boundary-free upper conductive film 4031.

It is noted that the above procedure may be repeated for many times to eventually obtain a barrier layer film comprising a plurality of grain-boundary-free upper conductive films 4031 and the lower conductive films 4032 of metal element Zr. In this case, a barrier layer 40 comprising a plurality of barrier units 403 can be obtained by performing one patterning process on the barrier layer film, and each barrier unit 403 comprises a grain-boundary-free upper conductive film 4031 and a lower conductive film 4032 of metal Zr element.

Furthermore, the resistivity and transparency of the barrier layer 40 as well as the overall thickness of the TFT will influence the performance of the TFT. Therefore, to guarantee the transparency and low resistivity of the barrier layer 40, a thickness of the eventually obtained barrier layer 40 with multiple of barrier units 40 should be less than or equal to 1500 Å.

As the upper conductive film 4031 is a grain-boundary-free conductive film, it can cover the lower conductive film 4032 and insulate the lower conductive film 4032 from the electrodes comprising copper, thereby preventing the diffusion of copper atoms 60.

Method 3

With reference to FIG. 4, the barrier layer film comprises a third conductive film 404 made of metal element Hf, and a thickness of the third conductive film 404 is 30˜1500 Å. The barrier layer 40 further comprises grain boundary blockages 80 at grain boundaries 70 of the third conductive film 404, the grain boundary blockages 80 are oxynitride of the metal element Hf, that is hafnium oxynitride, and are configured for filling the grain boundaries 70 of the third conductive film 404.

Herein, comprising the grain boundary blockages 80 at the grain boundaries 70 of the third conductive film 404 may be implemented in the following way. For example, the metal element Hf is deposited on a substrate by sputtering or thermal evaporation as the third conductive film 404; a mixture of nitrogen and oxygen under plasma condition is introduced to a surface of the third conductive film 404 of the metal element Hf; hafnium atoms at the surface of the third conductive film 404 react with the mixture of nitrogen and oxygen under plasma condition to form the grain boundary blockages 80 of hafnium oxynitride. The grain boundary blockages 80 of hafnium oxynitride can migrate to the grain boundaries 70 at the surface of the third conductive film 404, driven by the high-speed mixture of nitrogen and oxygen under plasma condition, and block the grain boundaries 70. As a result, when the barrier layer 40 is applied to a TFT having metal electrodes made of copper, the grain boundary blockages 80 can prevent the diffusion of the copper atoms 60 to the semiconductor active layer 30, thereby reducing the harm to the performance of the TFT device.

S105: forming a copper metal film on the substrate after step S104, forming a source/drain electrode layer 50 comprising a source electrode 501 and a drain electrode 502 above the bather layer 40 through one patterning process.

For example, a layer of copper metal film with a thickness of 1000˜7000 Å is deposited on the whole substrate via CVD, and the source electrode 501 and the drain electrode 502 can be formed by performing one patterning process on the metal oxide semiconductor film.

A bottom-gate TFT as illustrated in FIG. 5 may be fabricated by the above steps S101 to S105. The above barrier layer 40 between the source/drain metal layer 50 and the semiconductor active layer 30, it can prevent the copper atoms in the source/drain metal layer 50 from diffusing, which in turn reduces the harm to the performance of the TFT.

Based on the above array substrate, the invention further provides a method for fabricating the above array substrate. The fabrication method comprises the following step in addition to the above steps S101 to S105:

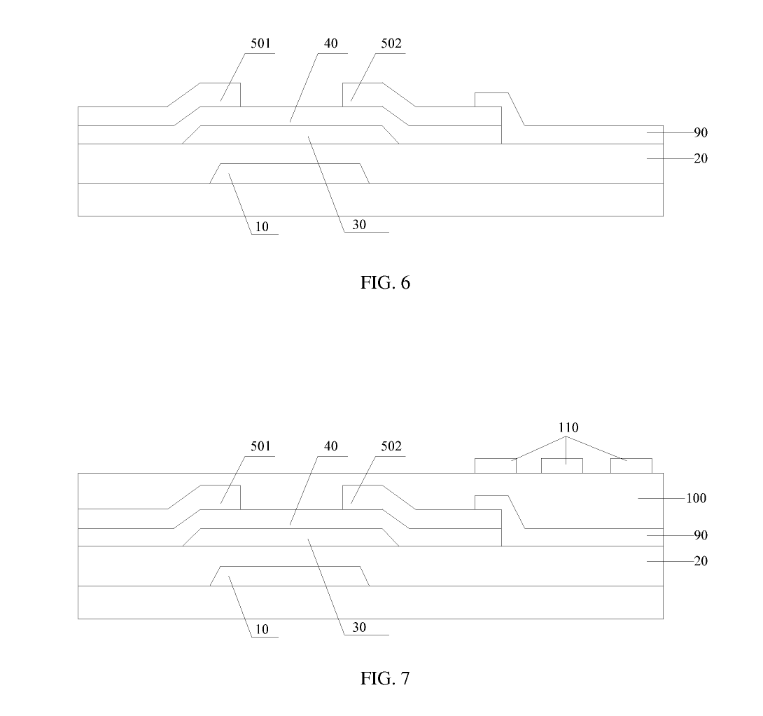

S106: forming a transparent conductive film on the substrate after step S105, forming a pixel electrode 90 electrically connected to the drain electrode 502 as illustrated in FIG. 6 through one patterning process.

For example, a transparent conductive film with a thickness of 100˜1000 Å may be deposited on the whole substrate by CVD, and a common transparent conductive film may be Indium Tin Oxides (ITO) or Indium Zinc Oxide (IZO) film. The pixel electrode 90 electrically connected to the drain electrode 502 may be formed through one patterning process.

The array substrate as illustrated in FIG. 6 may be fabricated through the above steps S101˜S106.

Furthermore, the array substrate provided by the embodiment of the invention may be applied to the production of LCDs such as ADS LCDs and TN LCDs.

The essential technical feature of the ADS technology is as follows: a multi-dimensional electric field is formed from both an electric field produced at edges of slit electrodes on the same plane and an electric field produced between a slit electrode layer and a plate electrode layer, so that liquid crystal molecules at all orientations, which are located directly above the electrodes and between the slit electrodes in a liquid crystal cell, can be rotated and aligned, which enhances the work efficiency of liquid crystals and increases light transmittance. The ADS technology can improve the picture quality of TFT-LCDs and has advantages of high transmissivity, wide viewing angles, high aperture ratio, low chromatic aberration, low response time, no push Mura, etc.

Therefore, an example of the method may preferably comprise the following steps in addition to step S106:

S107: forming a passivation layer 100 as illustrated in FIG. 7 on the substrate after step S106.

For example, a protection layer having a thickness of 1000˜6000 Å may be coated on the whole substrate, and a material of the protection layer is generally silicon nitride or transparent organic resin.

S108: forming a transparent conductive film on the substrate after step S107, and forming a common electrode 110 as illustrated in FIG. 7 through one patterning process.

The ADS type array substrate as illustrated in FIG. 7 can be obtained through the above steps S101˜S108.

What are described above is related to the illustrative embodiments of the disclosure only and not limitative to the scope of the disclosure; the scopes of the disclosure are defined by the accompanying claims.

1. A barrier layer, comprising at least two layers of conductive films, wherein grain boundaries in any layer of the conductive films are arranged in a staggered manner relative to grain boundaries in another layer of the conductive films contacting therewith.

2. The barrier layer of claim 1, wherein the at least two layers of conductive films comprise at least a first layer of conductive film and a second layer of conductive film, and both the first layer of conductive film and the second layer of conductive film comprise metal elements having high thermal stability and low resistivity.

3. The barrier layer of claim 1, wherein the at least two layers of conductive films comprise at least a first layer of conductive film and a second layer of conductive film, the first layer of conductive film comprises a metal element having high thermal stability and low resistivity; and
the second layer of conductive film comprises a compound or an alloy formed from the metal element having high thermal stability and low resistivity; and
wherein the compound comprises oxide, nitride, or oxynitride formed from the metal element having high thermal stability and low resistivity.

4. The barrier layer of claim 2, wherein the metal element having high thermal stability and low resistivity comprises molybdenum, titanium, tungsten, tantalum, zirconium, cobalt or hafnium.

5. The barrier layer of claim 2, wherein a thickness of any layer of the conductive films is 30˜500 Å.

6. A barrier layer, comprising at least one barrier unit, wherein any barrier unit comprises a layer of upper conductive film and a layer of lower conductive film, and the upper conductive film comprises a grain-boundary-free conductive film.

7. The barrier layer of claim 6, wherein the lower conductive film comprises a metal element having high thermal stability and low resistivity or an alloy formed from the metal element having high thermal stability and low resistivity.

8. The barrier layer of claim 7, wherein the metal element having high thermal stability and low resistivity comprises molybdenum, titanium, tungsten, tantalum, zirconium, cobalt or hafnium.

9. The barrier layer of claim 6, wherein a thickness of any barrier unit is 30˜300 Å.

10. A barrier layer, comprising:
a third conductive film having grain boundaries, and
grain boundary blockages at the grain boundaries of the third conductive film, for filling the grain boundaries of the third conductive film.

11. The barrier layer of claim 10, wherein the third conductive film comprises a metal element having high thermal stability and low resistivity or an alloy formed from the metal element having high thermal stability and low resistivity; and
the grain boundary blockages comprise oxide, nitride, or oxynitride formed from the metal element having high thermal stability and low resistivity.

12. The barrier layer of claim 11, wherein the metal element having high thermal stability and low resistivity comprises molybdenum, titanium, tungsten, tantalum, zirconium, cobalt or hafnium.

13. The barrier layer of claim 10, wherein a thickness of the third conductive film is 30˜1500 Å.

14. A thin film transistor (TFT), comprising a gate electrode, a gate insulation layer, a semiconductor active layer, a source/drain metal layer, and the barrier layer of claim 1.

15. An array substrate, comprising a substrate and a TFT disposed on the substrate, wherein the TFT is the TFT of claim 14.

16. A method for fabricating a barrier layer, comprising forming at least two layers of conductive films on a base substrate;
wherein grain boundaries in any layer of the conductive films is arranged in a staggered manner relative to grain boundaries in another layer of the conductive films contacting therewith.

17. The method of claim 16, wherein at least a first layer of conductive film and a second layer of conductive film layer both comprising metal elements having high thermal stability and low resistivity are formed on the base substrate.

18. The method of claim 16, wherein at least a first layer of conductive film comprising a metal element having high thermal stability and low resistivity and a second layer of conductive film comprising a compound or an alloy formed from the metal element having high thermal stability and low resistivity are formed on the base substrate.

19. The method of claim 17, wherein the metal element having high thermal stability and low resistivity comprises molybdenum, titanium, tungsten, tantalum, zirconium, cobalt or hafnium.

20. The method of claim 17, wherein a thickness of any layer of the conductive films is 30˜500 Å.

21. A method for fabricating a barrier layer, comprising forming at least a barrier unit on a base substrate, wherein any barrier unit comprises a layer of upper conductive film and a layer of lower conductive film, and
wherein the upper conductive film comprises a grain-boundary-free conductive film.

22. The method of claim 21, comprising: forming, on the base substrate, a layer of lower conductive film, wherein the lower conductive film comprises a metal element having high thermal stability and low resistivity or an alloy formed from the metal element having high thermal stability and low resistivity;
introducing oxygen, or nitrogen or a mixture of oxygen and nitrogen to a surface of the lower conductive film that faces the base substrate to form the upper conductive film, wherein the upper conductive film is a grain-boundary-free conductive film.

23. The method of claim 22, wherein the metal element having high thermal stability and low resistivity comprises molybdenum, titanium, tungsten, tantalum, zirconium, cobalt or hafnium.

24. The method of claim 21, wherein a thickness of any barrier unit is 30˜300 Å.

25. A method for fabricating a barrier layer, comprising forming a third conductive film having grain boundaries on a base substrate, and forming grain boundary blockages at the grain boundaries of the third conductive film, the grain boundary blockages being configured for filling the grain boundaries of the third conductive film.

26. The method of claim 25, wherein the third conductive film comprises a metal element having high thermal stability and low resistivity or an alloy formed from the metal element having high thermal stability and low resistivity.

27. The method of claim 26, wherein oxygen, or nitrogen or a mixture of oxygen and nitrogen is introduced to a surface of the third conductive film that faces the base substrate, to form the grain boundary blockage at the grain boundaries of the third conductive film, the grain boundary blockage being configured for filling the grain boundaries of the third conductive film;
wherein the grain boundary blockage comprises oxide, nitride, or oxynitride formed from the metal element having high thermal stability and low resistivity.

28. The method of claim 26, wherein the metal element having high thermal stability and low resistivity comprises molybdenum, titanium, tungsten, tantalum, zirconium, cobalt or hafnium.

29. The method of claim 25, wherein a thickness of the third conductive film is 30˜1500 Å.
